(19) United States
(12) Patent Application Publication
(10) Pub. No.: US 2026/0123399 A1
(43) Pub. Date: Apr. 30, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: XIAOFEI HAN, Singapore (SG); ZHIBIAO ZHOU, Singapore (SG); JIANFEI CUI, Singapore (SG)

(73) Assignee: UNITED MICROELECTRONICS CORP., Hsin-Chu City (TW)

(21) Appl. No.: 18/946,829

(22) Filed: Nov. 13, 2024

(30) Foreign Application Priority Data
Oct. 25, 2024 (TW) 113140729

(51) Int. Cl. H01L 23/522; H01L 21/768; H01L 23/532

(52) U.S. Cl. CPC H10W 20/496; H10W 20/072; H10W 20/46; H10W 20/48

(57) ABSTRACT

A method for fabricating a semiconductor device includes the steps of first forming an inter-metal dielectric (IMD) layer on the logic region and the capacitor region of a substrate, forming a first metal interconnection in the IMD layer of the logic region and a second metal interconnection in the IMD layer of the capacitor region, removing the IMD layer adjacent to the second metal interconnection, and then forming a high-k dielectric layer on the first metal interconnection and extending to the second metal interconnection. Preferably, the high-k dielectric layer encloses an air gap.

### BACKGROUND OF THE INVENTION

### 1. Field of the Invention

The invention relates to a method for fabricating a semiconductor device, and more particularly to a method of forming air gaps within metal interconnect structure.

### 2. Description of the Prior Art

As device dimensions continue to shrink, a reduction in interconnect line widths leads to increased line resistance (R) for signals. Further, reduced spacing between conducting lines creates more parasitic capacitance (C). The result is an increase in RC signal delay, which slows chip speed and lowers chip performance.

The line capacitance, C, is directly proportional to the dielectric constant, or k-value of a dielectric material. A low-k dielectric reduces the total interconnect capacitance of the chip, reduces the RC signal delay, and improves chip performance. Lowering the total capacitance also decreases power consumption. The use of a low-k dielectric material in conjunction with a low-resistance metal line provides an interconnect system with optimum performance for the ULSI technology. For this reason, prior art attempts to reduce the RC delays have focused on utilizing material with a low-k to fill the gaps between the metal lines.

Silicon dioxide (SiO₂) has been conventionally preferred as a dielectric material even though it has a relatively high dielectric constant (relative to vacuum) of about 4.1 to 4.5 because it is a thermally and chemically stable material and conventional oxide etching techniques are available for high-aspect-ratio contacts and via holes. However, as device dimensions decrease and the packing density increases, it is necessary to reduce the spacing between conductive lines to effectively wire up the integrated circuits. Therefore, a large number of lower dielectric constant materials are currently being investigated to reduce the RC value of the chip further. These include among many others fluorinated SiO₂, aerogels, and polymers. Another method being proposed to lower the dielectric constant even further is to form air gaps between the interconnect lines. While silicon dioxide has a dielectric constant of about 4 and greater, the dielectric constant of air is about 1.

Although air is the best dielectric material for lowering the RC value, unfortunately the use of air gap structures in integrated circuit fabrication has been hindered with problems. Overall mechanical strength of the device is reduced correspondingly and lead to structural deformation and a weakened structure can have serious effect in various aspects of subsequent integrated circuit fabrication. Accordingly, what is needed in the art is an air gap interconnect structure and method of manufacture thereof that addresses the above-discussed issues.

### SUMMARY OF THE INVENTION

According to an embodiment of the present invention, a method for fabricating a semiconductor device includes the steps of first forming an inter-metal dielectric (IMD) layer on the logic region and the capacitor region of a substrate, forming a first metal interconnection in the IMD layer of the logic region and a second metal interconnection in the IMD layer of the capacitor region, removing the IMD layer adjacent to the second metal interconnection, and then forming a high-k dielectric layer on the first metal interconnection and extending to the second metal interconnection. Preferably, the high-k dielectric layer encloses an air gap.

According to another aspect of the present invention, a semiconductor device includes a first metal interconnection on a logic region and a second metal interconnection on a capacitor region and a high-k dielectric layer adjacent to the second metal interconnection. Preferably, the high-k dielectric layer encloses an air gap.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating metal interconnect structure according to an embodiment of the present invention.

FIG. 7 illustrates a top view of metal interconnections on the logic region and capacitor region according to an embodiment of the present invention.

### DETAILED DESCRIPTION

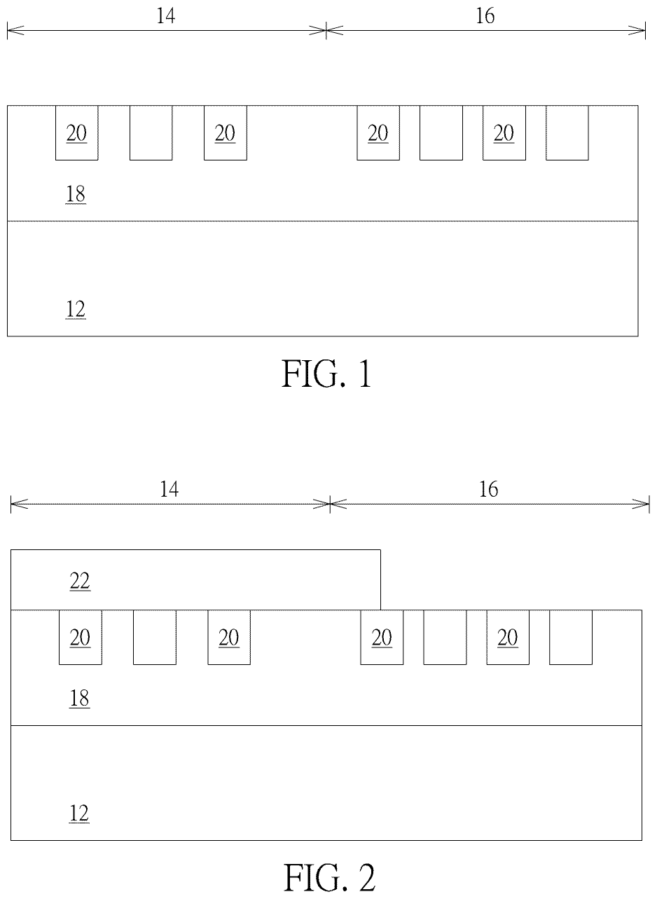

Referring to FIGS. 1-6, FIGS. 1-6 illustrate a method for fabricating metal interconnect structure according to an embodiment of the present invention. As shown in FIG. 1, a substrate 12, such as a substrate composed of semiconductor material is provided, in which the semiconductor material could be selected from the group consisting of silicon, germanium, silicon germanium compounds, silicon carbide, and gallium arsenide. Preferably, a logic region 14 having active devices such as metal-oxide semiconductor (MOS) transistors and a capacitor region 16 having capacitors are defined on the substrate 12.

Active devices such as metal-oxide semiconductor (MOS) transistors, passive devices, conductive layers, and interlayer dielectric (ILD) layer (not shown) could also be formed on top of the substrate 12. More specifically, planar MOS transistors or non-planar (such as FinFETs) MOS transistors could be formed on the substrate 12, in which the MOS transistors could include transistor elements such as metal gates and source/drain region, spacer, epitaxial layer, contact etch stop layer (CESL), the ILD layer could be formed on the substrate 12 and covering the MOS transistors, and a plurality of contact plugs could be formed in the ILD layer to electrically connect to the gate and/or source/drain region of MOS transistors. Since the fabrication of planar or non-planar transistors and ILD layer is well known to those skilled in the art, the details of which are not explained herein for the sake of brevity.

Next, an inter-metal dielectric (IMD) layer 18 is formed on the ILD layer on the logic region 14 and capacitor region 16 and then a metal interconnective process could be conducted to form metal interconnections 20 in the IMD layer 18. For instance, one or more photo-etching processes could be conducted to remove part of the IMD layer 18 for forming contact holes (not shown), conductive materials are deposited into each of the contact holes, and then a planarizing process such as chemical mechanical polishing (CMP) process is conducted to remove part of the conductive materials for forming the metal interconnections 20, in which the metal interconnections 20 could be connected to the MOS transistors and/or capacitors on the substrate 12. According to an embodiment of the present invention, the metal interconnection 20 could be fabricated in the IMD layer 18 according to a single damascene process or dual damascene process. For instance, the metal interconnection 20 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Since the single damascene process or dual damascene process are well known to those skilled in the art, the details of which are not explained herein for the sake of brevity.

In this embodiment, the metal interconnections 20 are preferably composed of copper and the IMD layer 18 is composed of silicon oxide such as tetraethyl orthosilicate (TEOS). Alternatively, the IMD layer 18 could also include an ultra low-k (ULK) dielectric layer including but not limited to for example porous material or silicon oxycarbide (SiOC) or SiOCH, which are all within the scope of the present invention.

Next, as shown in FIG. 2, a patterned mask 22 such as patterned resist is formed to cover the IMD layer 18 and metal interconnections 20 on the logic region 14 and expose the IMD layer 18 and metal interconnections 20 on the capacitor region 16.

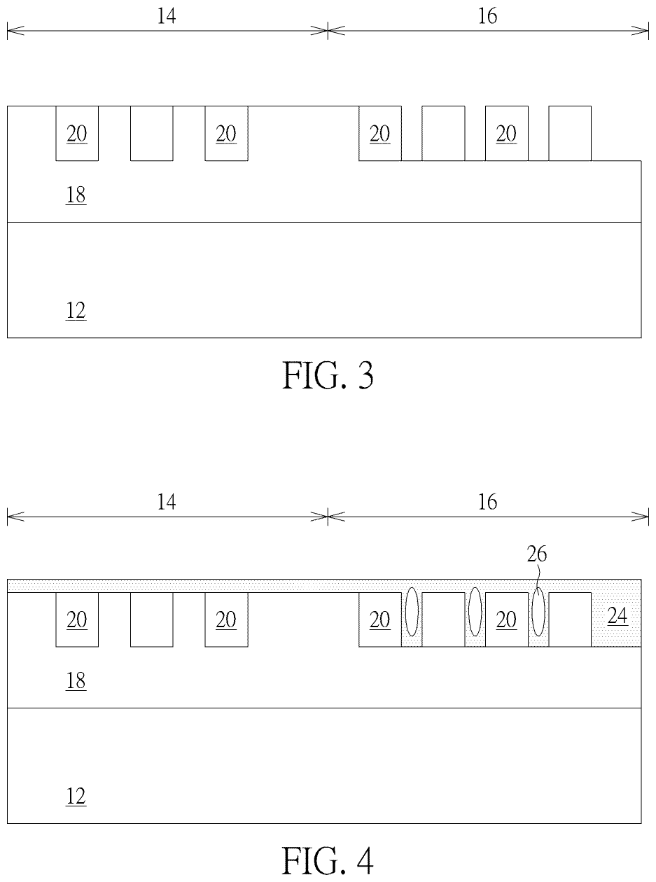

Next, as shown in FIG. 3, an etching process such as dry etching process is conducted by using the patterned mask 22 as mask to remove part of the IMD layer 18 on the capacitor region 16 so that the top surface of the remaining IMD layer 18 is even with the bottom surface of the metal interconnections 20. This also exposes the top surface and part of the sidewalls of the metal interconnections 20. It should be noted that even though the top surface of the remaining IMD layer 18 is even with the bottom surface of the metal interconnections 20 after the aforementioned etching process in this embodiment, according to other embodiment of the present invention, after the etching process were conducted to remove part of the IMD layer 18 on the capacitor region 16, the top surface of the remaining IMD layer 18 could be slightly lower than or slightly higher than the bottom surface of the metal interconnections 20, which are all within the scope of the present invention.

Next, as shown in FIG. 4, a high-k dielectric layer 24 is formed on the IMD layer 18 and metal interconnections on both logic region 14 and capacitor region 16, in which the high-k dielectric layer 24 preferably extends from the top surface of the IMD layer 18 and metal interconnections 20 on the logic region 14 to top surface and sidewalls of the metal interconnections 20 on the capacitor region 16 and fill into the gaps between the metal interconnections 20 to form air gaps 26. In other words, each of the air gaps 26 between the metal interconnections 20 on the capacitor region 16 is enclosed entirely by the high-k dielectric layer 24 while no air gap is formed between metal interconnections 20 on the logic region 14 as the metal interconnections 20 are surrounded by the IMD layer 18 entirely.

Preferably, the height of the high-k dielectric layer 24 is slightly higher than the height of the metal interconnections 20, in which the bottom surface of the high-k dielectric layer 24 is even with the bottom surface of the metal interconnections 20 and the top surface of the high-k dielectric layer 24 is slightly higher than the top surface of the metal interconnections 20. The height of the air gaps 26 between the metal interconnections 20 on the other hand could be adjusted according to the height of the high-k dielectric layer 24. For instance, the top surface of the air gaps 26 could be lower than, even with, or higher than the top surface of the IMD layer 20 on two adjacent sides, which are all within the scope of the present invention.

In this embodiment, the height of the high-k dielectric layer 24 is preferably between 50-100 Angstroms and the dielectric constant of the IMD layer 18 is less than the dielectric constant of the high-k dielectric layer 24. For instance, the high-k dielectric layer 24 is selected from dielectric materials having dielectric constant (k value) larger than 4, and the high-k dielectric layer 24 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

Next, as shown in FIG. 5, another set of metal interconnect structure is formed on the high-k dielectric layer 24 on both logic region 14 and capacitor region 16 to electrically connect to the lower level metal interconnections 20. For instance, a stop layer 28 and another IMD layer 38 could be formed on the surface of the high-k dielectric layer 24. In this embodiment, the stop layer 28 could include nitrogen doped carbide (NDC), silicon nitride (SiN), silicon carbon nitride (SiCN), or silicon oxynitride (SiON) and the IMD layer 38 could include silicon oxide such as tetraethyl orthosilicate (TEOS) or an ultra low-k (ULK) dielectric layer including but not limited to for example porous material or silicon oxycarbide (SiOC) or SiOCH, which are all within the scope of the present invention.

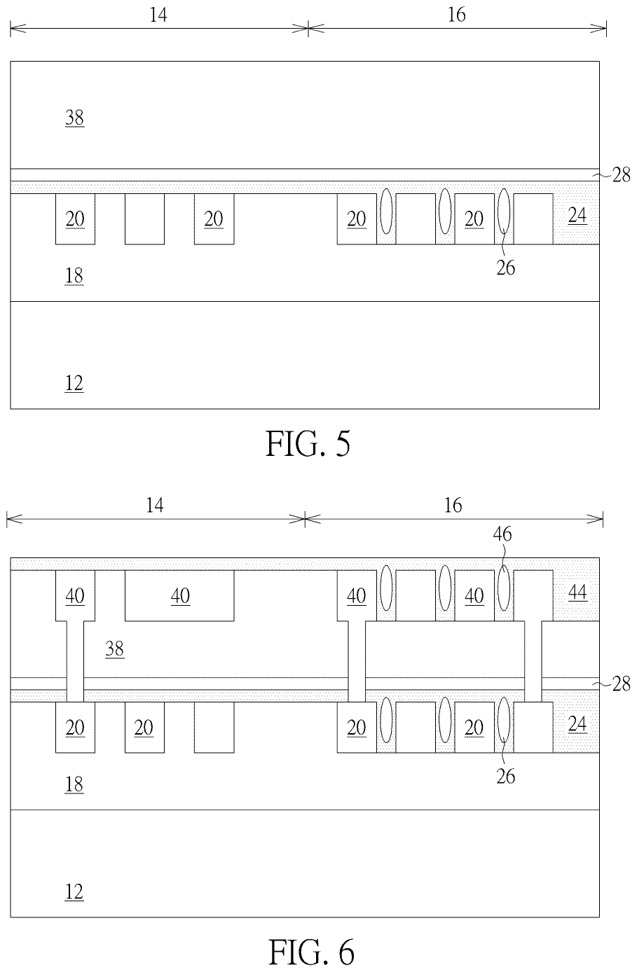

Next, as shown in FIG. 6, metal interconnect process conducted in FIGS. 1-4 could be repeated by first forming metal interconnections 40 in the IMD layer 28 on the logic region 14 and capacitor region 16 to electrically connect the lower level metal interconnections 20. For instance, a photo-etching process could be conducted to remove part of the IMD layer 38, part of the stop layer 28, and part of the high-k dielectric layer 24 for forming contact holes and then conductive or metal materials are deposited into the contact holes along with a CMP process to form metal interconnections 40, in which part of the metal interconnections 40 could be directly connected to the lower level metal interconnections 20 while remaining metal interconnections 40 could remain floating in the IMD layer 38.

Next, processes conducted in FIGS. 2-4 could be repeated by using a patterned mask (not shown) as mask to remove part of the IMD layer 38 on the capacitor region 16 so that the top surface of the remaining IMD layer 38 is even with the bottom surface of the metal interconnections 40 while top surface and sidewalls of part of the metal interconnections 40 are exposed. Next, a high-k dielectric layer 44 is formed to cover the IMD layer 38 and metal interconnections 40 on the logic region 14 and capacitor region 16, in which the high-k dielectric layer 44 preferably extends from the top surface of the IMD layer 38 and metal interconnections 40 on the logic region 14 to top surface and sidewalls of the metal interconnections 40 on the capacitor region 16 and fill into the gaps between the metal interconnections 40 to form air gaps 46.

Similar to the lower level metal interconnections 20 and air gaps 26, the height of the air gaps 46 between the metal interconnections 40 could be adjusted according to the height of the high-k dielectric layer 44. For instance, the top surface of the air gaps 46 could be lower than, even with, or higher than the top surface of the IMD layer 40 on two adjacent sides, which are all within the scope of the present invention.

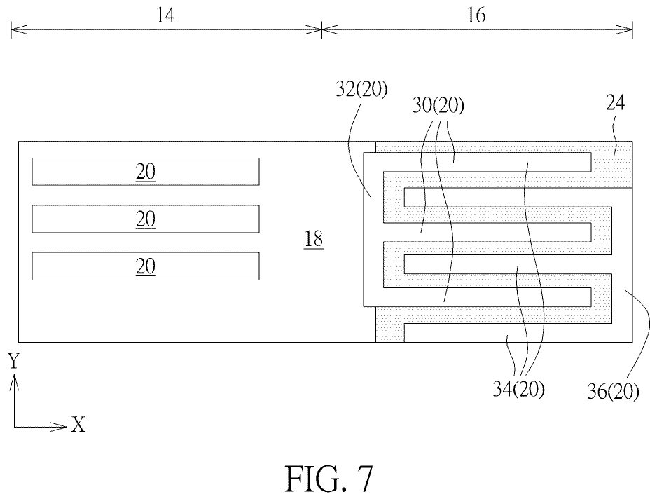

Referring to FIG. 7, FIG. 7 illustrates a top view of metal interconnections on the logic region and capacitor region according to an embodiment of the present invention. As shown in FIG. 7, after the high-k dielectric layer 24 and air gaps 26 are formed in FIG. 4, the metal interconnections 20 on the logic region 14 if viewed from a top view perspective preferably extends along a single direction such as X-direction in the IMD layer 18 while the metal interconnections 20 on the capacitor region 16 are extending in a finger-shape pattern in the IMD layer 18 for maximizing capacitance area of the device.

Specifically, the metal interconnections 20 on the capacitor region 16 include a set of metal interconnections 30 extending along the X-direction on the left side and a metal interconnection 32 extending along the Y-direction for connecting the metal interconnections 30 and another set of metal interconnections 34 extending along the X-direction on the right side and a metal interconnection 36 extending along the Y-direction for connecting the metal interconnections 34, in which the metal interconnections 30 and 34 extending along the same X-direction are disposed according to a staggered arrangement. The high-k dielectric layer 24 on the other hand is disposed according to a serpent shape around the metal interconnections 20 and in the IMD layer 18, in which the high-k dielectric layer 24 includes multiple U-shape turns immediately adjacent and directly contacting sidewalls of the metal interconnections 20.

Overall, the present invention first forms metal interconnections 20 in the IMD layer 18 on logic region and capacitor region, removes part of the IMD layer on the capacitor region, and then forming a high-k dielectric layer 24 on top surface and sidewalls of the metal interconnections on the capacitor regions while forming air gaps 26 between the metal interconnections. By using this design, it would be desirable to maintain substantially lower dielectric constant around metal interconnections on logic region for lowering RC delay while increasing overall capacitance on the capacitor region with the high-k dielectric material around metal interconnections.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a first metal interconnection on a logic region and a second metal interconnection on a capacitor region; and
forming a high-k dielectric layer adjacent to the second metal interconnection, wherein the high-k dielectric layer encloses an air gap.

2. The method of claim 1, further comprising:
forming an inter-metal dielectric (IMD) layer on the logic region and the capacitor region of a substrate;
forming the first metal interconnection and the second metal interconnection in the IMD layer;
removing the IMD layer adjacent to the second metal interconnection; and
forming the high-k dielectric layer on the first metal interconnection and extending to the second metal interconnection.

3. The method of claim 2, further comprising forming the high-k dielectric layer on top surfaces of the first metal interconnection and the IMD layer on the logic region.

4. The method of claim 2, further comprising forming the high-k dielectric layer on a top surface and a sidewall of the second metal interconnection on the capacitor region.

5. The method of claim 2, further comprising forming the high-k dielectric layer on the second metal interconnection and at the same time forming the air gap adjacent to the second metal interconnection.

6. The method of claim 2, wherein a dielectric constant of the IMD layer is less than a dielectric constant of the high-k dielectric layer.

7. A semiconductor device, comprising:
a first metal interconnection on a logic region and a second metal interconnection on a capacitor region; and
a high-k dielectric layer adjacent to the second metal interconnection, wherein the high-k dielectric layer encloses an air gap.

8. The semiconductor device of claim 7, further comprising:
an inter-metal dielectric (IMD) layer on the logic region and the capacitor region of a substrate; and
the first metal interconnection and the second metal interconnection in the IMD layer.

9. The semiconductor device of claim 7, wherein the high-k dielectric layer is on top surfaces of the first metal interconnection and the IMD layer on the logic region.

10. The semiconductor device of claim 7, wherein the high-k dielectric layer is on a top surface and a sidewall of the second metal interconnection on the capacitor region.

11. The semiconductor device of claim 8, wherein a dielectric constant of the IMD layer is less than a dielectric constant of the high-k dielectric layer.
